(19) United States
(12) Patent Application Publication
(10) Pub. No.: US 2007/0084043 A1
(43) Pub. Date: Apr. 19, 2007

(54) Conductive Adhesive Attachment of Capacitor Terminals

(75) Inventor: Terry Alan Hosking, Barre, VT (US)

Correspondence Address: MR. TERRY ALAN HOSKING, 44 LAWRENCE AVENUE, BARRE, VT, 05641, US

(73) Assignee: SB ELECTRONICS, Barre, VT (US)

(21) Appl. No.: 11/538,216

(22) Filed: Oct. 3, 2006

Related U.S. Application Data
(60) Provisional application No. 60/596,708, filed on Oct. 14, 2005.

(51) Int. Cl. H01L 21/00

(52) U.S. Cl. 29/621; 361/306.1; 29/25.01; 29/25.03

(57) ABSTRACT

An improved electrical terminal attachment process for a wound polymer film/foil or metallized film capacitor is described that minimizes thermal damage to the capacitor structure and improves the current carrying capability of the capacitor. The process employs an electrically conductive adhesive that can be cured at low temperatures. The disclosed process improves the reliability of the capacitor when used at high RMS or pulsed currents. It also enables capacitor application structures with reduced equivalent series inductance that would be otherwise difficult or impossible to fabricate.

### CROSS REFERENCE TO PRIOR APPLICATION

This application claims priority of U.S. Provisional Application Ser. No. 60/596,708 filed Oct. 14, 2005 and entitled “Conductive Adhesive Attachment of Capacitor Terminals,” the subject matter of which is incorporated herein by reference.

### FIELD OF INVENTION

The present invention relates to a process for attaching electrical terminals that results in a polymeric metallized film or film/foil wound capacitor with increased current carrying capability and reduced parasitic impedance, making it useful for high current applications.

### DESCRIPTION OF THE PRIOR ART

Wound film capacitor construction is well known prior art. In a metallized film wound capacitor, the metallized film is wound up in a roll, with each film layer extending to one side of the wound section. In a film/foil wound capacitor, a metallic foil is placed next to the film and the composite of film and metallic foil is wound up in a roll. Connection to the metallization and/or foil is made by spraying molten metal droplets against each end of the capacitor, building up a thickness of “end spray metal” sufficient for attaching electrical terminations. This technique is known as “schooping” and is disclosed by Hunt in U.S. Pat. No. 4,226,011 issued Oct. 7, 1980. For film capacitors, in particular but not limited to metallized film capacitors, the most common method of connecting a terminal/lead to the capacitor is by soldering the terminals or lead wires to the end-spray metal previously applied to the ends of the wound roll of metallized film. Normally, the solder temperature (up to 300 degrees Celcius) is so much higher than the melting point of the polymer film (typically 100-150 degrees Celcius), it destroys the contact between the end-spray and the metallization under and around the soldered area. The resulting electrical disconnection between the metallization and the end-spray metal layer leads to several problems. The significance of those problems depends on the application. After the capacitor terminals/leads are attached, the capacitor will have higher losses, lower current capability, and much less resistance to further metallization contact loss in applications where the capacitor is rapidly charged or discharged. The solder process significantly limits the electrical performance of metallized or film/foil capacitors, especially as the ratio of contact damage to total contact surface increases. This often occurs for very small diameter capacitors, or if large leads and/or terminals are used for high current applications.

Other known lead/terminal attachment art have been previously disclosed. See for example, Lavene, U.S. Pat. No. 4,685,026 issued Aug. 4, 1987; Saban U.S. Pat. No. 4,242,717 issued Dec. 30, 1980; Lavene, U.S. Pat. No. 4,614,995 issued Sep. 30, 1986; Shiota et al. in U.S. Pat. No. 6,954,349 issued Oct. 11, 2005, and Rayburn in U.S. Pat. No. 4,535,381 issued Aug. 13, 1985. In these prior-art patents, the use of end-spray metallization is disclosed, but details of the method or methods used to attach electrical leads to the spray metallization are generally not given. Besides soldering, one common method uses an electric resistance weld process to substantially reduce the total heat energy used to attach the wires/terminals to the spray metallization. The damage to capacitors with resistance-welded terminal attachment is reduced in proportion to the reduction in peak temperature excursion experienced by the film, but there remain problems for the same reasons described above.

For those applications where the highest electrical performance is required, which often occurs when very high RMS (Root Mean Squared) or pulsed electrical currents must be carried by the capacitor, large leads and/or terminals must be used. These large leads and/or terminals require a corresponding increase in heat energy input to form a resistance weld between the lead and/or terminal and the end-spray metal, or an increased time to achieve the melting temperature for proper solder flow when using a soldering attachment process. Furthermore, the applied heat remains stored in the leads and/or terminals after the attachment process is complete. This stored heat continues to inflict damage to the film directly beneath the lead and/or terminal attachment area, resulting in continued destruction of the electrical contact between the end-spray metal and the metallized film. In the case of a film/foil capacitor, the increased latent heat is efficiently conveyed from the end-spray metal to the interior of the capacitor by the thermally conductive metallic foil layers. This results in melting of the film between the foil layers, causing permanent capacitor damage in regions that may be substantially removed from the lead and/or terminal attachment location(s).

There exists a need for a novel method or process to allow the attachment of physically large leads and/or terminals to wound film capacitors that causes minimal or no thermal damage to the dielectric film comprising the wound capacitor. The novel method or process should be easily implemented in a manufacturing environment, and allow attachment of leads and/or terminals that are not limited in size relative to the physical dimensions of the capacitor.

### SUMMARY OF THE PRESENT INVENTION

The disclosed invention makes use of a conductive adhesive to attach the lead and/or terminal to the end-spray metal, or to directly attach the lead and/or terminal to the contact region at the end of the wound film capacitor. The adhesive is selected to have a curing temperature that is substantially lower than the temperature at which damage or mechanical deformation is generated in the metallized film. This results in maintaining excellent contact between the termination and the capacitor by eliminating the damage associated with previous “metal fusing” attachment methods. The disclosed method allows very large terminals to be attached to the capacitor [relative to the capacitor size] without thermal damage to the insulating film comprising the capacitor. Each terminal or lead can be made sufficiently large to provide a robust mechanical fastening location for attaching the capacitor to a fixed support.

One advantage of the present invention is that it enables terminal attachment to the end-spray metallization on a wound capacitor with no electrical or mechanical damage to the capacitor film.

Another advantage of the present invention is that it allows the fabrication of wound capacitors with the highest possible reliability in applications where extremes of average or pulse current are required.

Another advantage of the present invention is that it allows the use of physically large terminals and/or leads that would be impossible to attach to the capacitor in any other way.

Another advantage of the present invention is that it allows the capacitor to be installed in a system [such as, but not limited to, part of a power bus structure] such that no intermediary “terminations” are required. This flexibility of connection allows system level size reduction and performance improvements unavailable and/or impractical using alternative terminal attachment methods.

### BRIEF DESCRIPTION OF DRAWINGS

FIG. 1 is a drawing of a prior art film capacitor.

FIG. 2 is a drawing of prior art, a cross section of the attachment region of an electrical termination welded or soldered to the end-spray layer of a wound film capacitor, showing the damaged region directly beneath the termination foot.

FIG. 3 is a drawing of a cross section of the attachment region of an electrical termination adhesively bonded to the end-spray layer of a wound film capacitor, showing no damage directly beneath the termination foot.

FIG. 4 is a drawing of a cross section of the attachment region of an electrical termination adhesively bonded to the end contact region of a wound film capacitor, showing no damage directly beneath the termination foot.

### DETAILED DESCRIPTION OF THE PREFERRED EMBODIMENTS

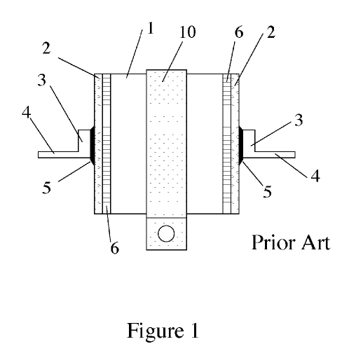

FIG. 1 is a drawing of prior art showing one end of a tubular shaped wound metallized film capacitor. The body of the capacitor 1 is comprised of multiple windings of metallized insulating film or multiple windings of a composite stack consisting of insulating film and metallic foil. At each end of the capacitor body, the metallized film or the film and metallic foil form an electrical contact region 6. An end-spray metallization layer 2 is applied using well-known processes to each electrical contact region 6 to form an intimate electrical connection with the plurality of conducting layers comprising the capacitor body 1. The end-spray metallization is preferably applied over the entire area of each end of the capacitor. An electrically conductive termination is comprised of a terminal foot 3 electrically connected with the terminal extension 4. Alternatively, an electrical lead can be used in place of the terminal 3 and 4. The terminal foot 3 is electrically and mechanically attached to the end-spray metallization layer 2 using welding or soldering techniques that are well known in the art. A second terminal foot 3 is attached to the opposite end of the capacitor body. During normal use, the capacitor body 1 may be mechanically supported by an additional mechanical fastening arrangement 10 affixed to the exterior of the capacitor body 1.

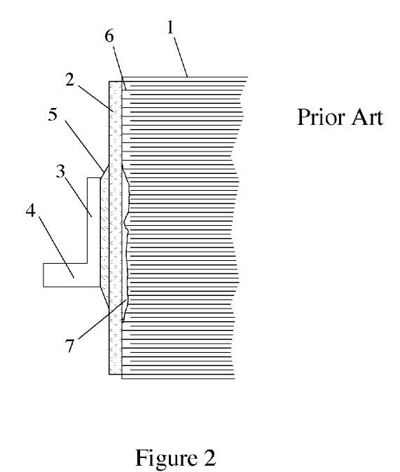

FIG. 2 is a drawing of prior art showing the cross sectional view of one end of the capacitor 1. The contact region 6 of the capacitor end region has an end-spray metallization layer 2 uniformly coating the capacitor end surface, forming electrical contact to the plurality of film or foil electrodes existing at the end of the wound film that forms the capacitor body 1. In this depiction of the prior art, a solder process is used to deposit solder 5 between the terminal foot 3 and the end-spray metallization 2. The soldering process consists of applying heat to the terminal foot 3 and the end-spray metallization 2 while holding the relative positions of the terminal foot 3 and the end-spray metallization 2 in a fixed relation with each other, until the melting temperature of the solder is achieved. This typically occurs at a temperature of 215-300 degrees Celcius. While heat continues to be applied to the joining region, solder is introduced into the region between the terminal foot 3 and the end-spray metallization 2. As the solder melts, sufficient solder is added to form an electrical connection between the terminal foot 3 and the end-spray metallization 2.

During the soldering process, the temperature of the soldered region must be raised above the melting point of the solder. This is often at temperatures that exceed the softening or melting point of the polymeric film forming the capacitor body. For example, lead-tin solders used in the electronics industry typically have melting points of more than 220 degrees Celcius. Film capacitors fabricated from Polypropylene will start to melt at temperatures exceeding 160 degrees Celcius. Because of the sustained excessive temperatures required by the soldering process, the capacitor film and metallization or foil is damaged directly beneath the terminal foot 3. This damaged region 7 results from a thermally induced pullback of the capacitor film, resulting in a loss of electrical contact in the entire region underneath and adjacent to the soldered surface. The loss of electrical contact leads to significant increases in the Equivalent Series Resistance (ESR) of the capacitor, since any currents flowing from the terminal 4 into the capacitor body 1 must flow an additional distance. In addition, the effective cross-sectional area of conductive material between the terminal foot 3 and the capacitor body 1 has also been reduced by the loss of electrical contact directly beneath the termination foot. Rather than flowing directly from left to right in FIG. 2, the termination current must flow vertically around the damaged region, resulting in additional resistive heating of the termination foot and the capacitor body during regular use.

A similar problem occurs when welding is used as the process to form the electrical connection between the terminal foot 3 and the end-spray metallization 2. In the case of a welding process, electrical cables are attached to the terminal 4 and the end-spray metallization 2, and carry a pulsed high current from a power supply. The high current generates high temperatures at the interface between the terminal foot 3 and the end-spray metallization 2, causing an intimate mechanical and electrical bond to form therein. The temperature of the region immediately adjacent to the weld will experience an elevated temperature, which can cause damage to the end contact region 6 as indicated by the damaged region 7 in FIG. 2.

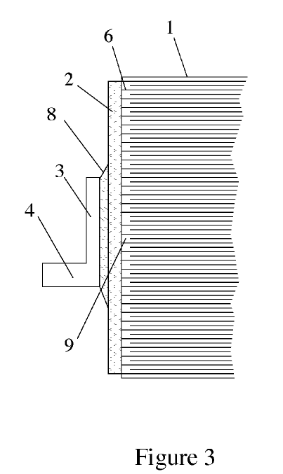

The disclosed invention avoids the thermal damage created in the soldering or welding processes. FIG. 3 is a cross sectional view of one of two or more termination contact regions of a wound film capacitor fabricated using the disclosed process. The method is comprised of attaching the terminal foot 3 to the end-spray metallization 2 using an electrically conductive adhesive 8. The electrically conductive adhesive 8 is then cured using methods well known in the art. For example, an electrically conductive epoxy can be cured by exposure to temperatures of 85 degrees Celcius for several hours, or by exposure to room temperature conditions for several days. The electrically conductive adhesive 8 is selected from the list including but not limited to epoxies, urethanes, silicones, methyl acrylates and cyanoacrylates. In each case the adhesive contains a substantial amount by volume of electrically conductive particles selected from the listed including but not limited to silver, nickel, carbon, gold, aluminum, platinum and/or copper. The adhesive should have a high electrical conductivity, to minimize any electrical losses that may occur as electrical current passes through the capacitor's terminals 4. The adhesive also forms a mechanical bond between the termination and the end-spray metallization. By selecting the adhesive so that it can be processed at temperatures below the damage temperatures of the capacitor film, the damage seen in solder or weld attachment methods is avoided, as indicated by the damage-free region 9 directly beneath the terminal foot 3.

The disclosed method can also be used with film/foil capacitors. In this case, the foils extending from each end of the wound capacitor body 1 are coated with end-spray metallization, as is done for metallized film capacitors. This provides a base to which the conductive adhesive will bond, as well as electrically connecting together all the foils accessible at one end of the capacitor for the lowest possible ESR (Equivalent Series Resistance) and ESL (Equivalent Series Inductance).

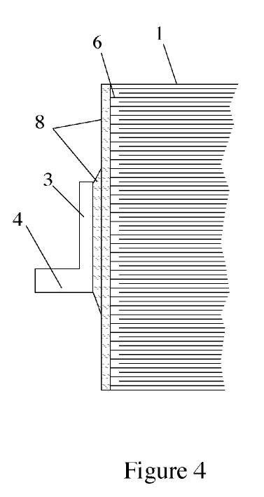

An alternative method disclosed in the present invention uses an electrically conductive adhesive to replace the end-spray metallization for metallized film or film/foil wound capacitors. As shown in FIG. 4, a layer of electrically conductive adhesive 8 is applied to the contact region 6. The adhesive is applied over substantially the entire contact region 6 and with sufficient thickness to provide a highly electrically conductive coating across the end surface of the capacitor once the adhesive is cured. The capacitor 1 and the terminal extension 4 and terminal foot 3 are positioned in a mechanical fixture, and the terminal foot 3 is then brought into contact with the adhesive coating 8. The adhesive is cured using techniques well known in the art. The process is repeated for each additional terminal being fastened to the capacitor 1. In this manner, the electrically conductive adhesive 8 performs the required functions of electrically interconnecting all of the individual metallizations and/or metal foils that are accessible on one end of the capacitor, electrically connecting the terminal foot 3 to the end of the capacitor, and providing a mechanical support point for the capacitor through the strong mechanical attachment created by the adhesive 8.

The disclosed invention has been reduced to practice as shown by the following example. A wound metallized film capacitor was fabricated in the shape of a donut with an inner radius of 42.5 mm, an outer radius of 82.5 mm, and a length of 60 mm using metallized polypropylene film having a thickness of 5.8 microns. The capacitance of the prototype device was approximately 500 microFarads, with a maximum operating voltage of 1800 VDC. An electrically conductive adhesive consisting of a silver-filed epoxy was employed to fasten a total of eight cable braids to each end of the capacitor. After appropriate curing of the epoxy, the capacitor was tested to determine if the region directly underneath each terminal foot 3 was damaged by the attachment process. The tests included repetitive electrical charging and discharging for over 10,000 cycles at peak discharge currents exceeding 50,000 Amperes with minimal damage to the capacitor. The damage was determined by making a measurement of the capacitance after a specified number of discharge cycles. Higher peak discharge currents of 130,000 Amperes resulted in capacitor degradation after approximately 100 cycles. These results greatly exceed the peak current capabilities of conventional metallized film wound capacitors. It should be noted that welding or soldering could not have been used to attach the large electrical braided terminals used in this example, since excessive thermal damage of the metallized film would have occurred, greatly reducing the reliability and peak current capability of the capacitor.

While only certain features of the invention have been illustrated and described herein, many modifications and changes will occur to those skilled in the art. It is, therefore, to be understood that the appended claims are intended to cover all such modifications and changes as fall within the true spirit of the invention.

What is claimed is:

1. A method of attaching electrical terminals to a wound polymeric capacitor selected from the list including but not limited to metallized film or film/foil, which minimizes thermal damage to the capacitor layers, comprising the steps of spraying hot metal particles on each end of the wound capacitor body, applying an electrically conductive adhesive to the sprayed metal coating on each end of the capacitor, affixing one or more electrically conducting terminals to each end of the capacitor using the electrically conductive adhesive as a binding medium, and curing the electrically conductive adhesive at a temperature substantially lower than that required to thermally damage or melt the film.

2. The method in claim 1 where the electrically conducting terminals are selected from the list that includes but is not limited to solid wire, stranded wire, wire braid, metallic lug, flat metallic plate, flat metallic plate with one or more threaded studs, or flat metallic plate with one or more threaded holes.

3. The method in claim 1 where at least one electrically conducting terminal is arranged to mechanically anchor the capacitor to a fixed support.

4. The method in claim 1 where the electrically conducting adhesive is comprised of an epoxy filled with electrically conductive particles selected from the list including but not limited to silver, nickel, tungsten, aluminum, copper and gold.

5. The method in claim 1 where the electrically conducting adhesive is comprised of a flexible silicone adhesive filled with electrically conductive particles selected from the list including but not limited to silver, nickel, tungsten, aluminum, copper and gold.

6. The method in claim 1 where the electrically conducting adhesive is comprised of a polyurethane adhesive filled with electrically conductive particles selected from the list including but not limited to silver, nickel, tungsten, aluminum, copper and gold.

7. The method in claim 1 where the metallized film or insulating film is selected from the list including but not limited to polypropylene, polyimide, polyester, polyethylene terephthalate, polyvinylidene difluoride and polystyrene.

8. A method of attaching electrical terminals to a wound polymeric capacitor selected from the list including but not limited to metallized film or film/foil, which minimizes thermal damage to the capacitor layers, comprising the steps of applying an electrically conductive adhesive to each end of the capacitor, affixing one or more electrically conducting terminals to each end of the capacitor using the electrically conductive adhesive as a binding medium, and curing the electrically conductive adhesive at a temperature substantially lower than that required to thermally damage or melt the film.

9. The method in claim 8 where the electrically conducting terminals are selected from the list that includes but is not limited to solid wire, stranded wire, wire braid, metallic lug, flat metallic plate, flat metallic plate with one or more threaded studs, or flat metallic plate with one or more threaded holes.

10. The method in claim 8 where at least one electrically conducting terminal is arranged to mechanically anchor the capacitor to a fixed support.

11. The method in claim 8 where the electrically conducting adhesive is comprised of an epoxy filled with electrically conductive particles selected from the list including but not limited to silver, nickel, tungsten, aluminum, copper and gold.

12. The method in claim 8 where the electrically conducting adhesive is comprised of a flexible silicone adhesive filled with electrically conductive particles selected from the list including but not limited to silver, nickel, tungsten, aluminum, copper and gold.

13. The method in claim 8 where the electrically conducting adhesive is comprised of a polyurethane adhesive filled with electrically conductive particles selected from the list including but not limited to silver, nickel, tungsten, aluminum, copper and gold.

14. The method in claim 8 where the metallized film or insulating film is selected from the list including but not limited to polypropylene, polyimide, polyester, polyethylene terephthalate, polyvinylidene difluoride and polystyrene.
